(19) United States
(12) Patent Application Publication
(10) Pub. No.: US 2012/0182031 A1
(43) Pub. Date: Jul. 19, 2012

(54) Test apparatus and test method

(75) Inventors: Isao Tokumoto, Saitama (JP); Kenji Hashimoto, Saitama (JP)

(73) Assignee: ADVANTEST CORPORATION, Tokyo (JP)

(21) Appl. No.: 13/180,551

(22) Filed: Jul. 12, 2011

(30) Foreign Application Priority Data
Aug. 2, 2010 (JP) 2010-173651

(51) Int. Cl. G01R 31/00

(52) U.S. Cl. 324/750.01

(57) ABSTRACT

Provided is a test apparatus that tests a device under test, comprising an inductance load section that is provided in a path through which test current flows to the device under test and that has an inductance component; a switching section that switches whether the test current is supplied to the device under test from the inductance load section; a cut-off control section that severs the path by switching the switching section according to a state of the device under test; and a voltage control section that controls voltage of the path between the inductance load section and the switching section to be no greater than a predetermined clamp voltage.

### BACKGROUND

1. Technical Field

The present invention relates to a test apparatus and a test method.

2. Related Art

In conventional methods for checking the safe operational range of a semiconductor device such as a MOSFET (metal oxide semiconductor field effect transistor) or an IGBT (insulated gate bipolar transistor), an avalanche breakdown test is performed when manufacturing the semiconductor. For example, Patent Document 1 discloses a test apparatus for performing an avalanche breakdown test.
Patent Document 1: Japanese Patent Application Publication No. 2007-33042

In the avalanche breakdown test, the device under test is connected to an inductance load such as an inductor, and electrical energy is accumulated in the inductance load while the device under test is in a conductive state. After this, the device under test is switched to a non-conductive state, and the endurance of the device under test is tested by applying the electrical energy accumulated in the inductance load to the device under test.

The current flowing through the device under test due to the application of a voltage that exceeds the rated value of the device under test while the device under test is in the non-conductive state is referred to as the “avalanche current.” The time during which the avalanche current flows is referred to as the “avalanche period.” The voltage applied to the device under test during the avalanche period is referred to as the avalanche voltage.

If the device under test malfunctions in a short-circuit mode during the avalanche period, an excessive current flows through the device under test. When this excessive current flows through the device under test, damage spreads in the device under test and it becomes difficult to analyze the cause of the malfunction of the device under test. Furthermore, the excessive current can damage the test apparatus. In order to prevent damage to the device under test and the test apparatus, when the device under test malfunctions, the current path from the inductance load is preferably severed quickly using a switch.

However, when the current path is severed while an excessive current is being supplied from the inductance load to the device under test, a counter electromotive force occurs in the inductance load. If the voltage caused by this counter electromotive force is greater than the avalanche voltage, the counter electromotive force can damage the switch. Furthermore, providing a switch with a withstand voltage high enough to handle the potential electromotive force incurs a high cost.

### SUMMARY

Therefore, it is an object of an aspect of the innovations herein to provide a test apparatus and test method, which are capable of overcoming the above drawbacks accompanying the related art. The above and other objects can be achieved by combinations described in the independent claims. According to a first aspect of the present invention, provided is a test apparatus that tests a device under test, comprising an inductance load section that is provided in a path through which test current flows to the device under test and that has an inductance component; a switching section that switches whether the test current is supplied to the device under test from the inductance load section; a cut-off control section that severs the path by switching the switching section according to a state of the device under test; and a voltage control section that controls voltage of the path between the inductance load section and the switching section to be no greater than a predetermined clamp voltage.

The switching section may be provided between the inductance load section and the device under test or between the device under test and a ground potential, and may switch whether the current flowing through the path is cut off. The cut-off control section may switch the switching section based on magnitude of the current flowing through the device under test or voltage between predetermined terminals of the device under test. The cut-off control section may switch the switching section based on a result of a comparison between a predetermined reference value and the magnitude of the current flowing through the device under test or the voltage between the terminals of the device under test at a predetermined comparison timing.

The inductance load section may include a plurality of inductance loads; and a selecting section that selects one or more of the inductance loads. The voltage control section may control the clamp voltage according to a combined inductance value of the one or more inductance loads selected by the inductance load section. The cut-off control section may control switching timing at which the switching section is switched, according to the combined inductance value of the one or more inductance loads selected by the inductance load section. The cut-off control section may control the comparison timing according to the combined inductance value of the one or more inductance loads selected by the inductance load section. The cut-off control section may control the reference value according to the combined inductance value of the one or more inductance loads selected by the inductance load section.

The test apparatus may further comprise a pulse signal supplying section that supplies the device under test with a pulse signal controlling the device under test to be in either a conductive state in which the test current flows therethrough or a non-conductive state in which the test current does not flow therethrough. When a predetermined time has passed since the pulse signal was supplied to the device under test, the cut-off control section may switch the switching section to an OFF state regardless of the state of the device under test.

The voltage control section may control the clamp voltage according to length of time during which the pulse signal is supplied to the device under test. The voltage control section may include a reference voltage generating section that generates a reference voltage corresponding to the clamp voltage; and a diode having a cathode connected to the reference voltage generating section and an anode connected between the inductance load section and the switching section. the voltage control section may include a reference voltage generating section that generates a reference voltage corresponding to the clamp voltage; and a switch that switches whether the reference voltage generating section is connected to the inductance load section and the switching section, according to the state of the switching section.

The cut-off control section may include a measuring section that measures one of a first elapsed time from when the supply of the pulse signal to the device under test begins and a second elapsed time from when the supply of the pulse signal to the device under test is stopped; a storage section that stores, in association with the measured elapsed time, at least one of a minimum value and a maximum value allowed for magnitude of the current flowing through the device under test; and a comparing section that compares the at least one of the minimum value and the maximum value stored in the storage section to the magnitude of the current flowing through the device under test. When the magnitude of the current flowing through the device under test at a predetermined comparison timing is less than the minimum value associated with the measured elapsed time corresponding to the comparison timing, or when the magnitude of the current flowing through the device under test at the predetermined comparison timing is greater than the maximum value associated with the measured elapsed time corresponding to the comparison timing, the comparing section may switch the switching section to cut off the supply of the test current from the inductance load section to the device under test.

The cut-off control section may include a measuring section that measures one of a first elapsed time from when the supply of the pulse signal to the device under test begins and a second elapsed time from when the supply of the pulse signal to the device under test is stopped; a storage section that stores, in association with the measured elapsed time, at least one of a minimum value and a maximum value allowed for voltage between predetermined terminals of the device under test; and a comparing section that compares the at least one of the minimum value and the maximum value stored in the storage section to the voltage between the predetermined terminals of the device under test. When the voltage between the predetermined terminals of the device under test at a predetermined comparison timing is less than the minimum value associated with the measured elapsed time corresponding to the comparison timing, or when the voltage between the predetermined terminals of the device under test at the predetermined comparison timing is greater than the maximum value associated with the measured elapsed time corresponding to the comparison timing, the comparing section may switch the switching section to cut off the supply of the test current from the inductance load section to the device under test.

The cut-off control section may include an AD converting section that converts current value flowing through the device under test or voltage value between predetermined terminals of the device under test into a digital signal.

The storage section may store at least one of the minimum value and the maximum value corresponding to the elapsed time, in association with an inductance value of the inductance load section, and the cut-off control section may switch the switching section based on the at least one of the minimum value and the maximum value corresponding to the inductance value of the inductance load section read from the storage section, according to the inductance value of the inductance load section.

The device under test may be a semiconductor device including a first terminal for receiving the test current, a second terminal for outputting the test current, and a third terminal for controlling the magnitude of the test current flowing between the first terminal and the second terminal, according to voltage or current input thereto, and the cut-off control section may switch the switching section according to the voltage between the first terminal and the second terminal or the voltage between the second terminal and the third terminal. The test apparatus may further comprise a power supply section that supplies current input to the inductance load section.

According to a second aspect of the present invention, provided is a test method for testing a device under test, comprising controlling a switching section that switches whether test current is supplied to the device under test from an inductance load section having an inductance component and provided in a path through which the test current flows to the device under test, to sever the path according to a state of the device under test; and controlling voltage of the path between the inductance load section and the switching section to be no greater than a predetermined clamp voltage.

The summary clause does not necessarily describe all necessary features of the embodiments of the present invention. The present invention may also be a sub-combination of the features described above.

### BRIEF DESCRIPTION OF THE DRAWINGS

FIG. 1 shows a configuration of a test apparatus 100 according to an embodiment of the present invention.

FIG. 2 shows exemplary voltage and current in the test apparatus 100 and a correctly-operating device under test 200 during testing.

FIG. 3 shows exemplary voltage and current in the test apparatus 100 and a device under test 200 that does not operate correctly during testing.

FIG. 4 shows another exemplary configuration of the test apparatus 100 according to an embodiment of the present invention.

FIG. 5A shows an exemplary configuration of the inductance load section 110.

FIG. 5B shows an exemplary configuration of the inductance load section 110.

FIG. 5C shows an exemplary configuration of the inductance load section 110.

FIG. 6 shows another exemplary configuration of a test apparatus 100 according to an embodiment of the present invention.

FIG. 7 shows another exemplary configuration of a test apparatus 100 according to an embodiment of the present invention.

FIG. 8 shows another exemplary configuration of a test apparatus 100 according to an embodiment of the present invention.

FIG. 9A shows an exemplary configuration of the cut-off control section 130.

FIG. 9B shows another exemplary configuration of the cut-off control section 130.

FIG. 10A shows exemplary data stored in the storage section 134.

FIG. 10B shows exemplary data stored in the storage section 134.

FIG. 10C shows exemplary data stored in the storage section 134.

FIG. 11 shows an exemplary configuration of a test apparatus 100 according to another embodiment of the present invention.

### DESCRIPTION OF EXEMPLARY EMBODIMENTS

Hereinafter, some embodiments of the present invention will be described. The embodiments do not limit the invention according to the claims, and all the combinations of the features described in the embodiments are not necessarily essential to means provided by aspects of the invention.

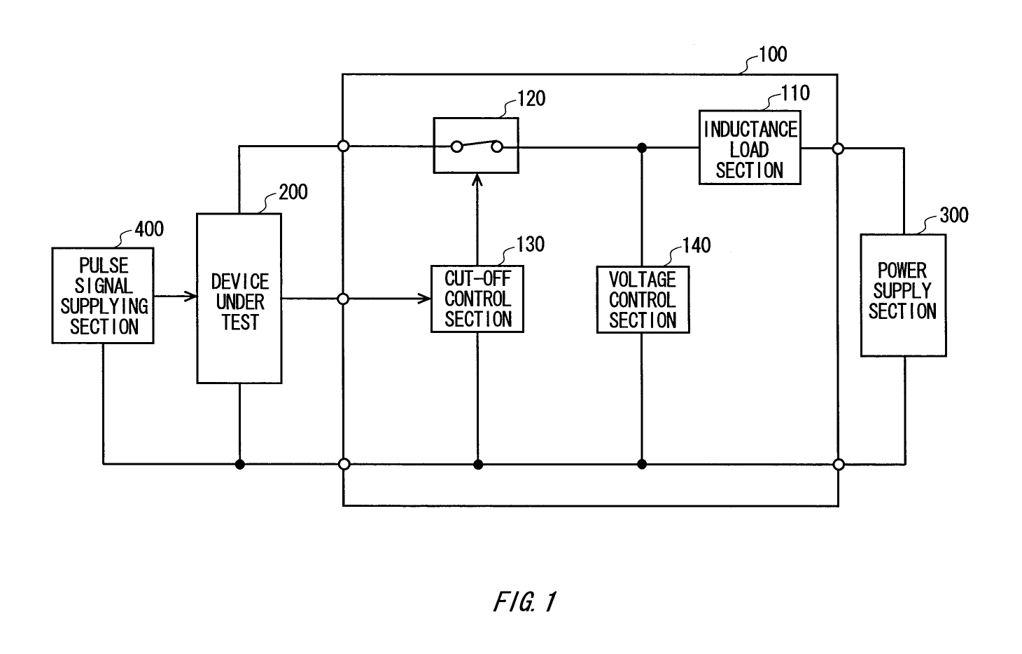

FIG. 1 shows a configuration of a test apparatus 100 according to an embodiment of the present invention. The test apparatus 100 tests a device under test 200. The test apparatus 100 includes an inductance load section 110, a switching section 120, a cut-off control section 130, and a voltage control section 140.

The inductance load section 110 is provided in a path through which test current flows to the device under test 200, and has an inductance component. Specifically, the inductance load section 110 is a passive element, such as an inductor, that has an inductance. The inductance load section 110 may receive current from a power supply section 300 connected to the test apparatus 100.

The pulse signal supplying section 400 supplies the device under test 200 with a pulse signal that controls the device under test 200 to be in a conductive state in which test current flows therethrough or a non-conductive state in which test current does not flow therethrough. In this Specification, “supplying a pulse signal” means inputting to the device under test 200 a signal having a voltage that is greater than or equal to a threshold voltage, to put the device under test 200 in the conductive state. Furthermore, “stopping the supply of the pulse signal” means inputting to the device under test 200 a signal having a voltage that is less than the threshold voltage, to put the device under test 200 in the non-conductive state.

If the device under test 200 is a semiconductor device such as a MOSFET having a drain terminal, a source terminal, and a gate terminal or an IGBT having a collector terminal, an emitter terminal, and a gate terminal, the state of the device under test 200 is changed to have a conductive state between the drain terminal and the source terminal or a conductive state between the collector terminal and the emitter terminal, according to the voltage of the pulse signal input to the gate terminal. If the device under test 200 is an n-channel MOSFET, for example, the conductive state between the drain terminal and the source terminal occurs when the gate voltage is greater than or equal to the threshold voltage, thereby causing the test current to flow from the inductance load section 110 to the device under test 200. Similarly, if the device under test 200 is an IGBT, the conductive state between the collector terminal and the emitter terminal occurs when the gate voltage is greater than or equal to the threshold voltage, thereby causing the test current to flow from the inductance load section 110 to the device under test 200.

The switching section 120 switches whether the test current from the inductance load section 110 is supplied to the device under test 200. The switching section 120 is provided between the inductance load section 110 and the device under test 200 or between the device under test 200 and a ground potential, and switches whether the current flowing in the path between the inductance load section 110 and the switching section 120 is cut off.

The switching section 120 may be a switch or relay, for example, that receives a control signal output by the cut-off control section 130, and switches between an ON state in which there is conduction between the inductance load section 110 and the device under test 200 and an OFF state in which there is no conduction between the inductance load section 110 and the device under test 200. The switching section 120 may be a mechanical relay that mechanically creates the ON state and the OFF state. The switching section 120 may be a semiconductor switch such as a bipolar transistor or a field effect transistor.

The cut-off control section 130 switches the switching section 120 according to the state of the device under test 200. Specifically, the cut-off control section 130 switches the switching section 120 based on the magnitude of the current flowing through the device under test 200 or the voltage between predetermined terminals of the device under test 200.

For example, the cut-off control section 130 may switch the switching section 120 to the OFF state when the current flowing through the device under test 200 is greater than the design value for the current that can flow through the device under test 200 during testing. The cut-off control section 130 may switch the switching section 120 to the OFF state when the current flowing through the device under test 200 is greater than a current value obtained as the sum of the design value for the current and a predetermined margin based on temperature fluctuation or voltage fluctuation.

The cut-off control section 130 may switch the switching section 120 based on the magnitude of the current flowing through the device under test 200 or the voltage between predetermined terminals of the device under test 200. For example, the cut-off control section 130 may switch the switching section 120 based on results of a comparison between a predetermined reference value and the magnitude of the voltage between terminals of the device under test 200 or the current flowing through the device under test 200 at a predetermined comparison timing. The comparison timing may indicate an elapsed time that has passed after an edge of the pulse signal output by a pulse signal supplying section 400, for example.

If the device under test 200 is a MOSFET having a drain terminal, a source terminal, and a gate terminal, the cut-off control section 130 may switch the switching section 120 to the OFF state when the voltage between the drain terminal and the source terminal is less than the design value. The cut-off control section 130 may switch the switching section 120 to the OFF state when the drain terminal and the source terminal are in a connected state. Similarly, if the device under test 200 is an IGBT, the cut-off control section 130 may switch the switching section 120 to the OFF state when the collector terminal and the emitter terminal are in a connected state.

After a predetermined time has passed from when the pulse signal was supplied to the device under test 200, the cut-off control section 130 may switch the switching section 120 regardless of the state of the device under test 200. For example, the cut-off control section 130 may switch the switching section 120 after the predetermined time has passed from a rising edge or a falling edge of the pulse signal.

The cut-off control section 130 may switch the switching section 120 to the OFF state after a time, calculated as the sum of the time when the pulse signal is supplied to the device under test 200 and a design value for the average time during which the test current flows from the inductance load section 110, has passed since the pulse signal was supplied to the device under test 200. The cut-off control section 130 may switch the switching section 120 to the OFF state according to the elapsed time since the supply of the pulse signal to the device under test 200 was stopped. By switching the switching section 120 to the OFF state after the predetermined time has passed, test current can be prevented from continuing to flow while the device under test 200 is malfunctioning.

The voltage control section 140 controls the voltage of the path between the inductance load section 110 and the switching section 120 to be less than or equal to a predetermined clamp voltage. Specifically, the voltage control section 140 receives the current output by the inductance load section 110 when the voltage in the path between the inductance load section 110 and the switching section 120 is the clamp voltage, and causes this current to flow to a ground terminal of the power supply section 300. The voltage control section 140 may be a surge absorber such as a varistor that causes current to flow when a voltage greater than or equal to a predetermined voltage is applied thereto, or a circuit including a reference voltage source and a diode.

By holding the voltage in the path between the inductance load section 110 and the switching section 120 to be less than or equal to the clamp voltage, the voltage control section 140 can prevent the spread of damage in the device under test 200 due to surge voltage generated when the switching section 120 is switched to the OFF state, and can also prevent damage to the switching section 120.

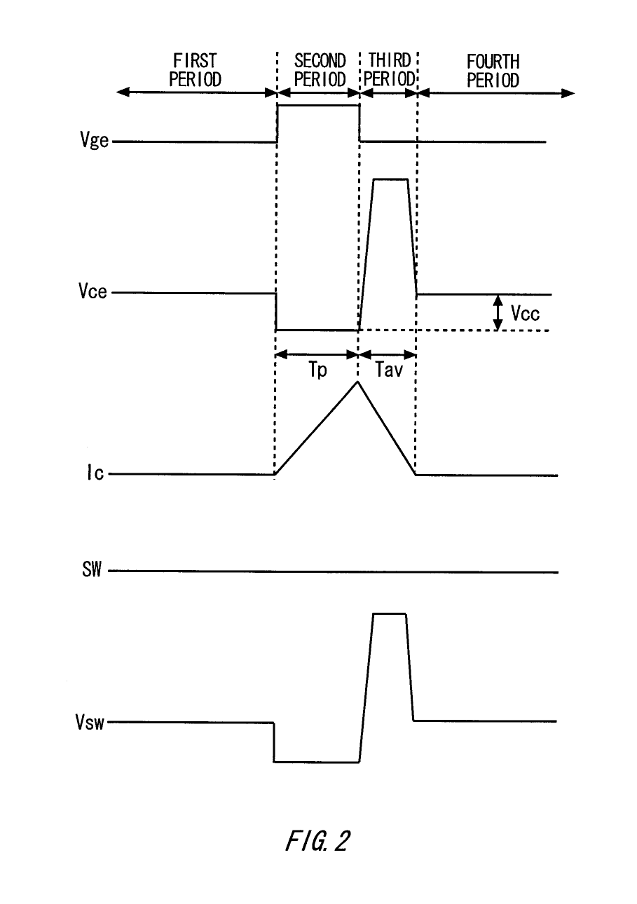

FIG. 2 shows exemplary voltage and current in the test apparatus 100 and a correctly-operating device under test 200 during testing. FIG. 2 shows waveforms obtained when an IGBT including a collector terminal, an emitter terminal, and a gate terminal is used as the device under test 200. Here, Vge represents the voltage between the gate terminal and the emitter terminal caused by the pulse signal supplied to the gate terminal of the device under test 200.

In FIG. 2, Vce represents the voltage between the collector terminal and the emitter terminal of the device under test 200, Ic represents the collector current flowing between the collector terminal and the emitter terminal of the device under test 200, and SW represents the conductive state of the switching section 120. In FIG. 2, the switching section 120 is always in the ON state, and therefore the waveform of SW does not change. Furthermore, Vsw represents the voltage of the path between the switching section 120 and the inductance load section 110, Tp represents the length of the pulse signal, and Tav represents the period during which the avalanche current flows in the correctly-operating device under test 200.

During the first period in which the pulse signal is not supplied to the gate terminal of the device under test 200, the device under test 200 is in the non-conductive state, and therefore the inductance load section 110 does not supply the test current to the device under test 200. When current is not flowing through the inductance load section 110, there is no potential difference between the ends of the inductance load section 110, and therefore the voltage of the collector terminal of the device under test 200 is equal to the voltage Vcc output by the power supply section 300. Accordingly, Vce is equal to Vcc during the first period.

During the second period in which the pulse signal is supplied to the gate terminal of the device under test 200, the collector current Ic flows between the collector terminal and the emitter terminal of the device under test 200. Since the collector current Ic is supplied through the inductance load section 110 that has an inductance, the current value increases with a rate of change dependent on the inductance value of the inductance load section 110 and electrical energy is accumulated in the inductance load section 110.

During the third period after the supply of the pulse signal to the gate terminal of the device under test 200 is stopped, the device under test 200 is in the non-conductive state and Vce increases quickly. In addition, the inductance load section 110 begins releasing the accumulated electrical energy. The device under test 200 absorbs the electrical energy released by the inductance load section 110 and converts this electrical energy into heat. The third period continues until all of the electrical energy accumulated in the inductance load section 110 is released. The third period in FIG. 2 is equivalent to the avalanche period.

In the example shown in FIG. 2, the device under test 200 absorbs the electrical energy released by the inductance load section 110 without malfunctioning, the avalanche period then ends, and the fourth period during which the current does not flow in the device under test 200 begins. In the fourth period, Vce is equal to the output voltage Vcc of the power supply section 300.

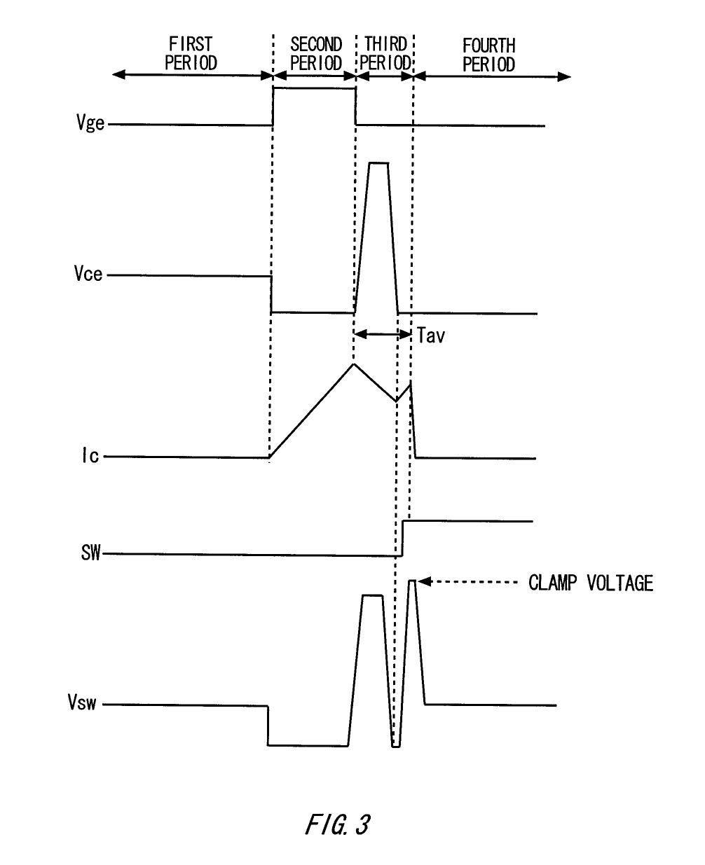

FIG. 3 shows exemplary voltage and current in the test apparatus 100 and a device under test 200 that does not operate correctly during testing. FIG. 3 shows waveforms of voltage or current obtained when an IGBT including a collector terminal, an emitter terminal, and a gate terminal is used as the device under test 200, in the same manner as in FIG. 2.

The waveforms in the first and second periods in FIG. 3 are the same as the corresponding waveforms in FIG. 2. However, during the third period, Vce drops to a level (0 V) that is the same as the level in the second period in which there is conduction between the collector terminal and the emitter terminal. This Vce drop is due to an excessive voltage being applied and the malfunctioning device under test 200 causing a connection between the collector terminal and the emitter terminal. As a result, the collector current Ic, which begins decreasing from the start of the third period, increases again.

When the increase in the collector current Ic continues, the damage to the device under test 200 can spread, making it difficult to analyze the device under test 200. Accordingly, when the collector current Ic has an abnormal value in the third period, the cut-off control section 130 preferably controls the switching section 120 to quickly stop the supply of the test current from the inductance load section 110 to the device under test 200. For example, when the collector current Ic is outside a predetermined range, the cut-off control section 130 switches the switching section 120 to the OFF state. As another example, the cut-off control section 130 may switch the switching section 120 to the OFF state when the collector current Ic changes from a decreasing state to an increasing state in the third period.

When the switching section 120 is switched to the OFF state, the collector current no longer flows through the device under test 200. However, a counter electromotive force occurs in the disconnected inductance load section 110, and therefore the voltage in the path between the inductance load section 110 and the switching section 120 quickly increases. The voltage control section 140 can prevent Vsw from exceeding the clamp voltage by causing the voltage in the path between the inductance load section 110 and the switching section 120 to be less than or equal to the predetermined clamp voltage.

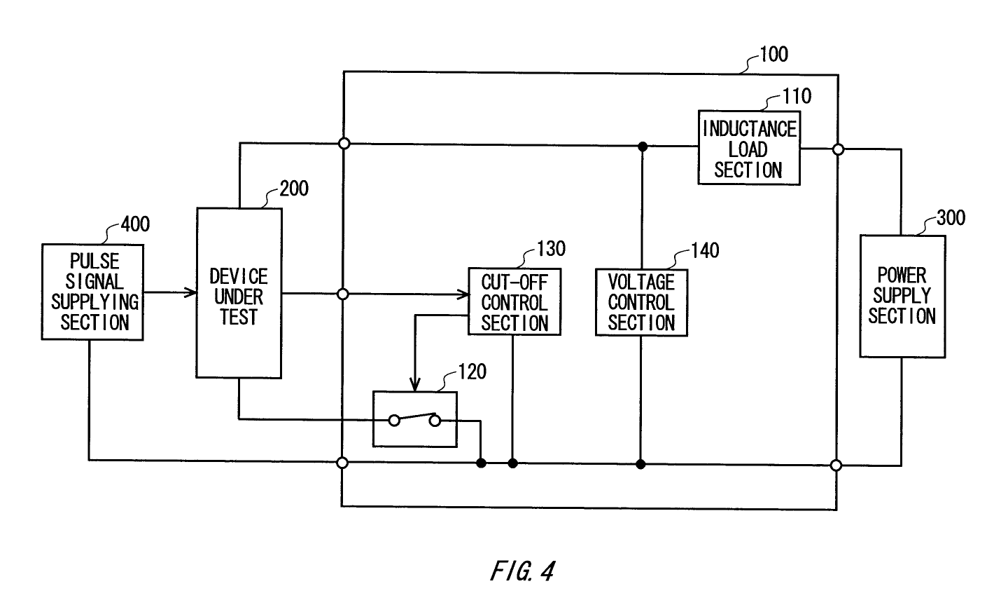

FIG. 4 shows another exemplary configuration of the test apparatus 100 according to an embodiment of the present invention. The test apparatus 100 of FIG. 4 has the switching section 120 located at a different position than the switching section 120 in the test apparatus 100 of FIG. 1. Specifically, the switching section 120 is connected to a terminal of the device under test 200 that outputs current. If the device under test 200 is a field effect transistor, the switching section 120 is arranged between the emitter terminal of the device under test 200 and a ground terminal of the power supply section 300.

When the cut-off control section 130 sets the switching section 120 to the OFF state, the voltage in the path between the inductance load section 110 and the device under test 200 increases quickly. The voltage control section 140 can prevent damage to the device under test 200 from spreading by controlling the voltage between the inductance load section 110 and the device under test 200 to be less than or equal to the clamp voltage.

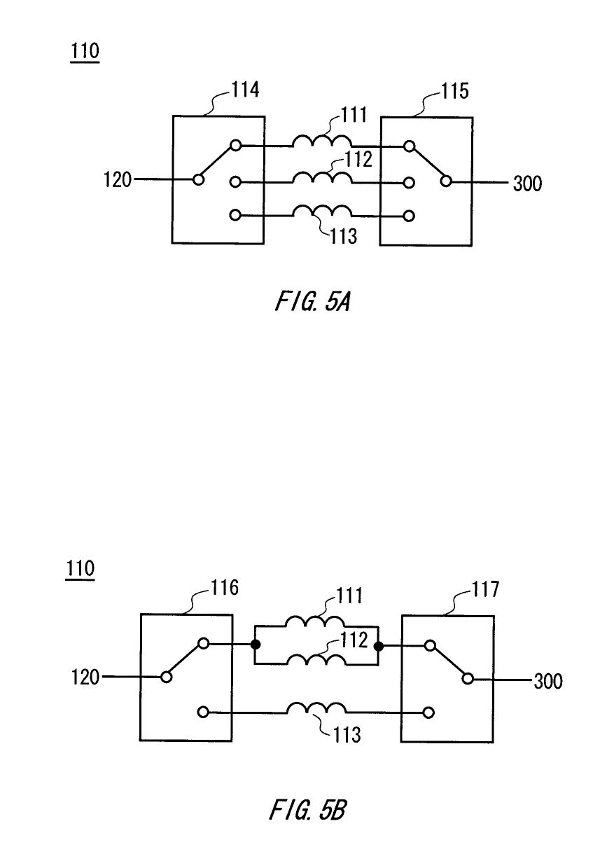

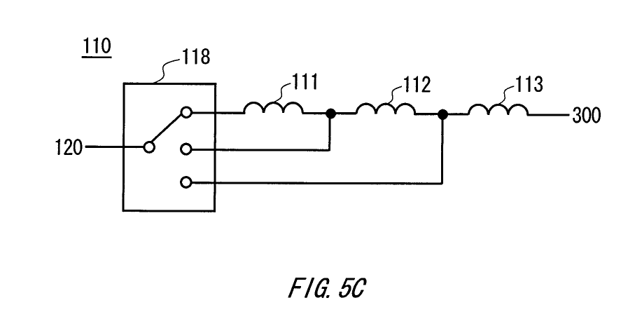

FIGS. 5A, 5B, and 5C show exemplary configurations of the inductance load section 110. The inductance load section 110 may include a plurality of inductance loads and a selecting section that selects one or more inductance loads from among the plurality of inductance loads. In FIG. 5A, the inductance load section 110 includes inductors 111, 112, and 113, which each have different inductance, and switches 114 and 115. The switch 114 selects one of the inductors 111, 112, and 113 and connects the selected inductor to the switching section 120. The switch 115 selects one of the inductors 111, 112, and 113 and connects the selected inductor to the power supply section 300. The inductance load section 110 can switch the inductance value by changing the connections of the switches 114 and 115.

In FIG. 5B, the inductance load section 110 includes switches 116 and 117 instead of the switches 114 and 115 shown in FIG. 5A. The switch 116 selects either the inductor 113 or the inductors 111 and 112 connected in parallel, and connects the selected inductor or inductors to the switching section 120. The switch 117 selects either the inductor 113 or the inductors 111 and 112 connected in parallel, and connects the selected inductor or inductors to the power supply section 300. The inductance load section 110 can switch the inductance value by changing the connections of the switches 116 and 117.

In FIG. 5C, the inductance load section 110 includes the inductors 111, 112, and 113 and a switch 118 connected in series. The switch 118 selects one of connecting the inductor 113 between the switching section 120 and the power supply section 300, connecting the inductors 112 and 113 between the switching section 120 and the power supply section 300, and connecting the inductors 111, 112, and 113 between the switching section 120 and the power supply section 300. The inductance load section 110 can switch the inductance value by changing the connection of the switch 118.

In the manner described above, the inductance load section 110 can switch among a plurality of different induction values according to the characteristics of the device under test 200 or the desired testing specifications, for example. The cut-off control section 130 may control the timing at which the switching section 120 switches according to the inductance value of the inductance load section 110. For example, the electrical energy accumulated in the inductance load section 110 may be greater when the inductance value of the inductance load section 110 is larger. Accordingly, in order to prevent damage to the device under test 200, the cut-off control section 130 preferably sets the switching section 120 to the OFF state at an earlier timing when the inductance value of the inductance load section 110 is larger.

The voltage control section 140 may control the clamp voltage according to the combined inductance value of the inductance load section 110. Different inductance values of the inductance load section 110 result in different amounts of electrical energy being accumulated in the inductance load section 110 during the second period shown in FIG. 2. Therefore, the maximum value of Vce also differs in the third period after the supply of the pulse signal to the device under test 200 is stopped.

When the clamp voltage is less than the maximum value of Vce in a correctly-operating device under test 200, the voltage applied to the device under test 200 during testing is the clamp voltage, and this situation is undesirable. Therefore, according to the combined inductance value of the inductance load section 110, the voltage control section 140 preferably controls the clamp voltage to be greater than the maximum voltage applied to the device under test 200 when testing a correctly-operating device under test 200 using this inductance value.

The voltage control section 140 may control the clamp voltage according to the electrical characteristics of the device under test 200. The design values for withstand voltage and other such characteristics depend on the type of device under test 200. Accordingly, the test apparatus 100 can test the device under test 200 using appropriate conditions by switching the time when the pulse signal is supplied and switching the inductance value of the inductance load section 110 according to the electrical characteristics of the device under test 200. In other words, different types of devices under test 200 have different maximum values for Vce in the third period after the supply of the pulse signal to the device under test 200 is stopped. Therefore, according to the electrical characteristics of the device under test 200, the voltage control section 140 preferably controls the clamp voltage to be greater than the maximum voltage applied to the device under test 200 when the device under test 200 is tested.

The voltage control section 140 may control the clamp voltage according to the length of time that the pulse signal is supplied to the device under test 200. Electrical energy continues to be accumulated in the inductance load section 110 while the pulse signal is supplied to the device under test 200 and the test current flowing through the device under test 200 increases. Accordingly, the maximum value of Vce occurring after the cut-off control section 130 switches the switching section 120 to the OFF state is increased. Therefore, the voltage control section 140 preferably uses a larger clamp voltage when the time during which the pulse signal is supplied to the device under test 200 is longer.

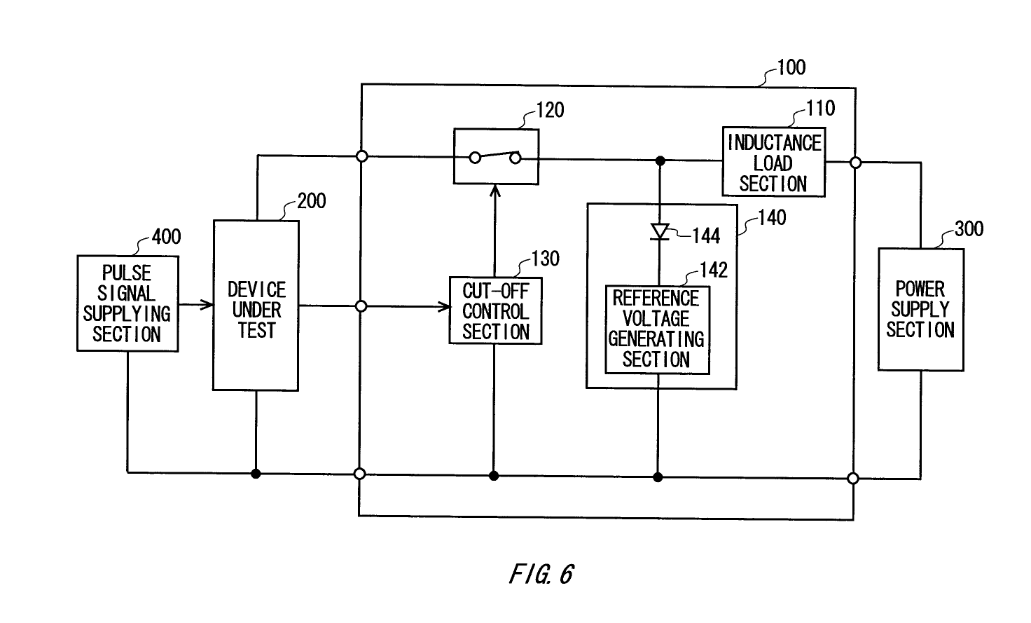

FIG. 6 shows another exemplary configuration of a test apparatus 100 according to an embodiment of the present invention. The voltage control section 140 in FIG. 6 includes a reference voltage generating section 142 and a diode 144 instead of the voltage control section 140 shown in FIG. 1. The reference voltage generating section 142 generates a reference voltage corresponding to the clamp voltage. The cathode of the diode 144 is connected to the reference voltage generating section 142, and the anode of the diode 144 is connected between the inductance load section 110 and the switching section 120.

When the voltage in the path between the inductance load section 110 and the switching section 120 is lower than the voltage at the connection point between the reference voltage generating section 142 and the diode 144, current does not flow to the diode 144. When the voltage in the path between the inductance load section 110 and the switching section 120 is higher than the voltage at the connection point between the reference voltage generating section 142 and the diode 144, a forward current flows through the diode 144, and therefore the voltage in the path between the inductance load section 110 and the switching section 120 is equal to the voltage at the connection point between the reference voltage generating section 142 and the diode 144. As a result, the voltage control section 140 can decrease the voltage in the path between the inductance load section 110 and the switching section 120 to be no greater than the reference voltage generated by the reference voltage generating section 142.

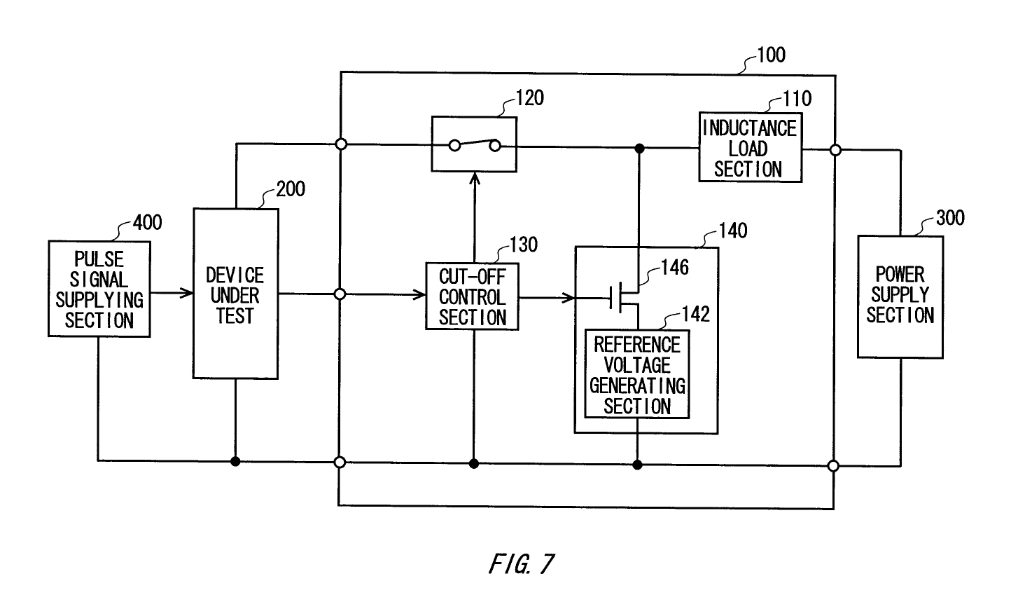

FIG. 7 shows another exemplary configuration of a test apparatus 100 according to an embodiment of the present invention. The voltage control section 140 in FIG. 7 includes a switch 146 instead of the diode 144 shown in FIG. 6. The switch 146 switches whether the reference voltage generating section 142 is connected to the inductance load section 110 and the switching section 120, according to the state of the switching section 120. The switch 146 may be a semiconductor switch such as a field effect transistor. The switch 146 may be a mechanical relay.

The cut-off control section 130 may switch the switching section 120 and the switch 146 in synchronization. Specifically, the cut-off control section 130 sets the switch 146 to the OFF state when the switching section 120 is in the ON state. By setting the switch 146 to the ON state at substantially the same time the switching section 120 is in the OFF state, the cut-off control section 130 can cause the surge current generated immediately after the switching section 120 switches to the OFF state to be absorbed by the voltage control section 140, thereby keeping the voltage in the path between the inductance load section 110 and the switching section 120 equal to the reference voltage output by the reference voltage generating section 142.

With the above configuration, the cut-off control section 130 can control the timing at which the switching section 120 is set to the OFF state and the timing at which the switch 146 is set to the ON state. Accordingly, the voltage control section 140 can control the voltage in the path between the inductance load section 110 and the switching section 120 with a shorter response time than the diode 144 shown in FIG. 6.

The cut-off control section 130 may control the switching times of the switching section 120 and the switch 146 according to the combined inductance value of the inductance load section 110. By performing this control, the cut-off control section 130 can control the voltage in the path between the inductance load section 110 and the switching section 120 at a timing suitable for each different surge waveform that depends on the inductance value of the inductance load section 110.

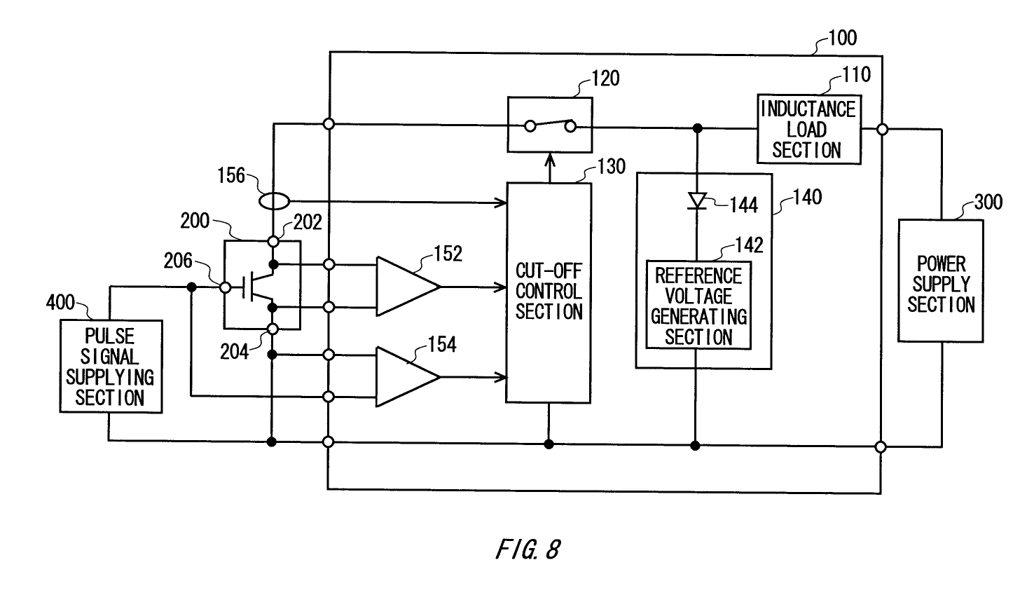

FIG. 8 shows another exemplary configuration of a test apparatus 100 according to an embodiment of the present invention. In this example, the device under test 200 is a semiconductor device that includes a first terminal for receiving the test current, a second terminal for outputting the test current, and a third terminal for controlling the magnitude of the test current flowing between the first terminal and the second terminal according to voltage or current input thereto. As shown in FIG. 8, if the device under test 200 is an IGBT, the first terminal corresponds to the collector terminal 202, the second terminal corresponds to the emitter terminal 204, and the third terminal corresponds to the gate terminal 206.

The test apparatus 100 further includes a voltage detecting circuit 152, a voltage detecting circuit 154, and a current detector 156 in addition to the configuration of the test apparatus 100 described in FIG. 1. The voltage detecting circuit 152 inputs, to the cut-off control section 130, the voltage between the collector terminal 202 and the emitter terminal 204 of the device under test 200. The voltage detecting circuit 154 inputs the voltage between the emitter terminal 204 and the gate terminal 206 to the cut-off control section 130. The cut-off control section 130 may switch the switching section 120 according to the voltage between the collector terminal 202 and the emitter terminal 204 or the voltage between the emitter terminal 204 and the gate terminal 206, for example. More specifically, when the voltage received from the voltage detecting circuit 152 is less than or equal to a predetermined voltage during a period in which the device under test 200 is in the non-conductive state, the cut-off control section 130 determines the device under test 200 to be in a short-circuit state and switches the switching section 120 to the OFF state.

The current detector 156 detects the collector current of the device under test 200. The current detector 156 may be a current detecting coil that is inserted in the path between the switching section 120 and the device under test 200, for example. The current detector 156 may input a voltage corresponding to the magnitude of the collector current to the cut-off control section 130, for example.

The cut-off control section 130 may control the switching section 120 based on the voltage output by at least one of the voltage detecting circuit 152, the voltage detecting circuit 154, and the current detector 156. The voltage output by the voltage detecting circuit 154 is equal to the voltage of the pulse signal supplied to the gate terminal 206 of the device under test 200. Accordingly, the cut-off control section 130 can detect the timing at which the pulse signal is supplied to the device under test 200 based on the voltage output by the voltage detecting circuit 154. Therefore, the cut-off control section 130 may control the switching section 120 according to whether the voltage output by the voltage detecting circuit 152 is within an allowable range at the timing of this detection based on the voltage output by the voltage detecting circuit 154.

If the device under test 200 is an n-channel IGBT, for example, the device under test 200 is in the OFF state during the avalanche period in which the pulse signal supplied to the gate terminal 206 of the device under test 200 is less than the threshold voltage of the device under test 200. Accordingly, when the device under test 200 operates correctly during the avalanche period, the voltage detecting circuit 152 outputs a voltage that is greater than or equal to the voltage output by the power supply section 300.

It should be noted that, regardless of the voltage output by the voltage detecting circuit 154 being less than or equal to the threshold voltage, when the voltage output by the voltage detecting circuit 152 is less than the voltage output by the power supply section 300, the device under test 200 could malfunction and enter the short-circuit state. Therefore, the cut-off control section 130 preferably switches the switching section 120 to the OFF state when the voltage output by the voltage detecting circuit 152 is less than a predetermined voltage such as the voltage output by the power supply section 300.

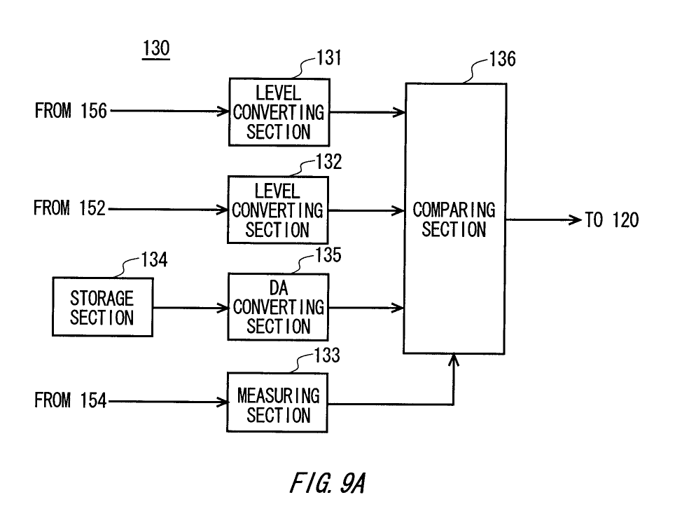

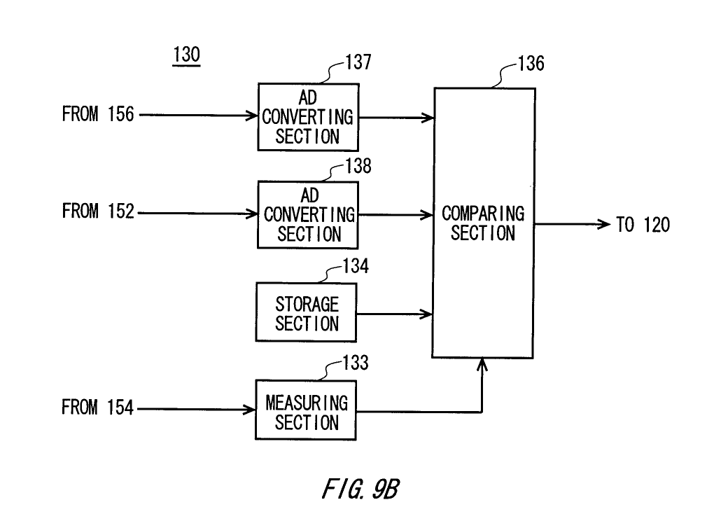

FIG. 9A shows an exemplary configuration of the cut-off control section 130. The cut-off control section 130 includes a level converting section 131, a level converting section 132, a measuring section 133, a storage section 134, a DA converting section 135, and a comparing section 136. The level converting section 131 converts the level of the voltage output by the current detector 156 and inputs the resulting analog signal to the comparing section 136. The level converting section 132 converts the level of the voltage between the collector terminal 202 and the emitter terminal 204 of the device under test 200, and inputs the resulting analog signal to the comparing section 136.

The measuring section 133 generates a signal indicating either a first elapsed time that passes from the timing at which the pulse signal is supplied to the device under test 200 or a second elapsed time that passes from the timing at which the supply of the pulse signal to the device under test 200 is stopped, based on the signal output by the voltage detecting circuit 154. For example, the measuring section 133 may generate the signal indicating this elapsed time by counting a clock with a prescribed frequency generated internally. The measuring section 133 inputs the generated signal to the comparing section 136.

The storage section 134 stores the allowable range for voltage between predetermined terminals of the device under test 200 or magnitude of the current flowing through the device under test 200, in association with one of the first elapsed time from the timing at which the pulse signal is supplied to the device under test 200 and the second elapsed time from the timing at which the supply of the pulse signal to the device under test 200 is stopped. For example, the storage section 134 may store the maximum value and minimum value allowed for the collector current of the device under test 200 in association with the first elapsed time, which is the elapsed time that passes from the timing at which the collector terminal 202 and the emitter terminal 204 enter the conductive state. The storage section 134 may store the maximum value and minimum value allowed for the collector current of the device under test 200 in association with the second elapsed time, which is the elapsed time that passes from the timing at which the collector terminal 202 and the emitter terminal 204 enter the non-conductive state.

Similarly, the storage section 134 may store the maximum value and minimum value allowed for the voltage between the collector terminal 202 and the emitter terminal 204 of the device under test 200 in association with the first elapsed time or the second elapsed time. The storage section 134 may store, in association with each elapsed time period corresponding to a predetermined time interval, the maximum value and minimum value allowed for the collector current of the device under test 200 or the maximum value and minimum value allowed for the collector-emitter voltage of the device under test 200.

The DA converting section 135 converts the maximum value and minimum value allowed for the collector current read from the storage section 134 or the maximum value and minimum value allowed for the collector-emitter voltage read from the storage section 134 into an analog signal. The DA converting section 135 inputs the converted analog signal to the comparing section 136.

The comparing section 136 compares the maximum value and minimum value allowed for the collector current stored in the storage section 134 to the magnitude of the current flowing through he device under test 200. The comparing section 136 compares the maximum value and minimum value allowed for the collector-emitter voltage stored from the storage section 134 to the voltage between the collector terminal 202 and the emitter terminal 204.

More specifically, the comparing section 136 compares the analog signal received from the level converting section 131 to the values associated with the signal indicating the elapsed time received from the measuring section 133 in the analog signal corresponding to the minimum value and maximum value of the collector current, which is received from the DA converting section 135. Furthermore, the comparing section 136 may compare the analog signal received from the level converting section 132 to the values associated with the signal indicating the elapsed time received from the measuring section 133 among the minimum values and maximum values of the collector-emitter voltage received from the DA converting section 135. The comparing section 136 may make these comparisons at a comparison timing corresponding to a timing that is a predetermined time after the supply of the pulse signal to the device under test 200 begins or a timing that is a predetermined time after the supply of the pulse signal to the device under test 200 is stopped.

More specifically, if the magnitude of the current flowing through the device under test 200 or the voltage between predetermined terminals of the device under test 200 at the predetermined comparison timing is less than the minimum value associated with this comparison timing among the minimum values stored in the storage section 134, the comparing section 136 may output a signal to switch the switching section 120. Similarly, if the magnitude of the current flowing through the device under test 200 or the voltage between predetermined terminals of the device under test 200 at the predetermined comparison timing is greater than the maximum value associated with this comparison timing among the maximum values stored in the storage section 134, the comparing section 136 may output a signal to switch the switching section 120. The switching section 120 cuts off the flow of the test current from the inductance load section 110 to the device under test 200 according to the signal output by the comparing section 136 for switching the switching section 120.

The collector-emitter voltage and the collector current flowing when the device under test 200 operates correctly change according to the inductance value of the inductance load section 110. To deal with this, the cut-off control section 130 may control the comparison timing according to the combined inductance value of the inductance load section 110. For example, when the inductance value of the inductance load section 110 is large, a large amount of electrical energy is accumulated in the inductance load section 110 and the avalanche period is lengthened, and therefore the cut-off control section 130 may cause the comparison timing to be later.

The cut-off control section 130 may control the reference value used for the comparison with the magnitude of the voltage between the terminals or the current flowing through the device under test 200 at the comparison timing, according to the combined inductance value of the inductance load section 110. For example, the storage section 134 may store at least one of a maximum value and a minimum value allowable for the collector-emitter voltage or the collector current corresponding to a certain elapsed time, in association with the combined inductance value of the inductance load section 110. The cut-off control section 130 may then switch the switching section 120 based on the at least one of the maximum value and minimum value corresponding to the inductance value of the inductance load section 110 read from the storage section 134, according to the inductance value of the inductance load section 110. The cut-off control section 130 can detect damage to the device under test 200 with a high degree of accuracy by changing the conditions for switching the switching section 120 according to the inductance value of the inductance load section 110, and can switch the switching section 120 to the OFF state when damage is detected.

FIG. 9B shows another exemplary configuration of the cut-off control section 130. The cut-off control section 130 in FIG. 9B includes an AD converting section 137, an AD converting section 138, the measuring section 133, the storage section 134, and the comparing section 136. The AD converting section 137 converts the voltage detected by the current detector 156 and corresponding to the collector current of the device under test 200 into a digital signal. The AD converting section 138 converts the voltage between the collector terminal 202 and the emitter terminal 204 of the device under test 200 into a digital signal.

The comparing section 136 compares the maximum value and minimum value allowable for the collector current stored in the storage section 134 to the value of the digital signal received from the AD converting section 137 and corresponding to the current flowing through the device under test 200. The comparing section 136 compares the maximum value and minimum value allowable for the collector-emitter voltage stored in the storage section 134 to the value of the digital signal received from the AD converting section 138 and corresponding to the voltage between the collector terminal 202 and the emitter terminal 204.

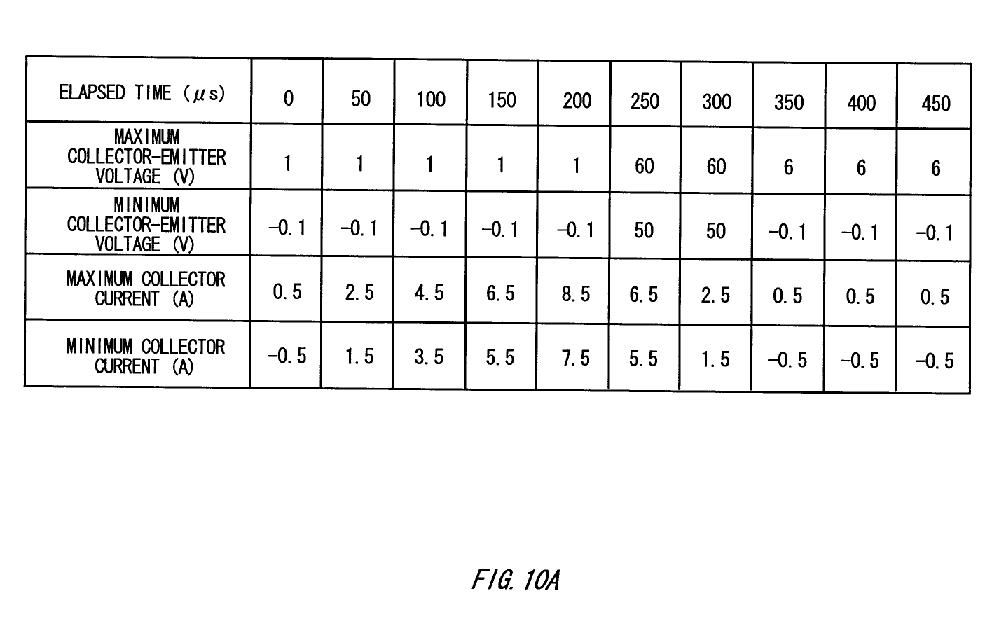

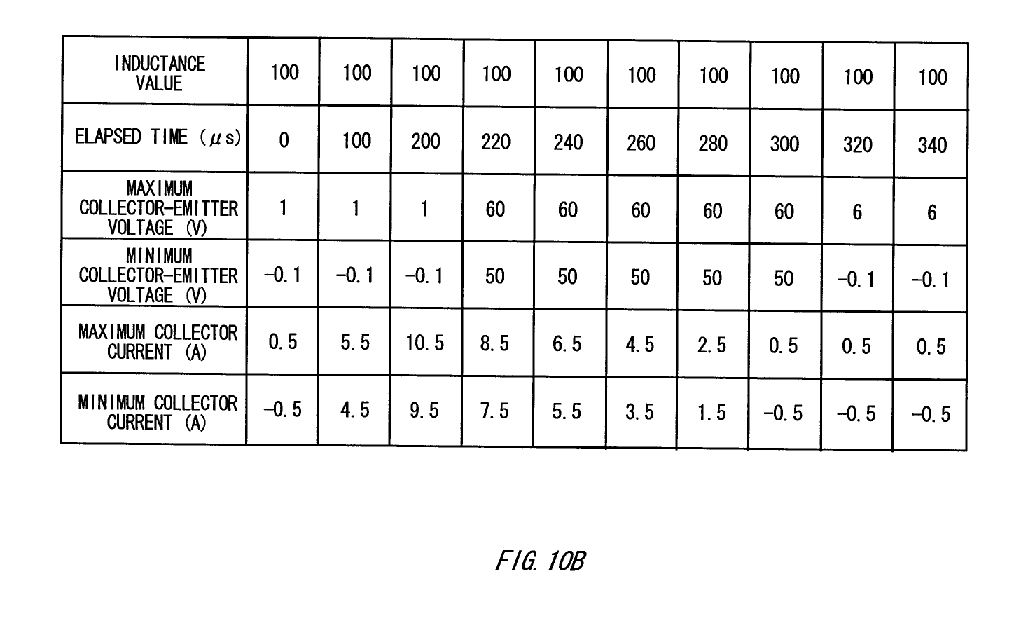

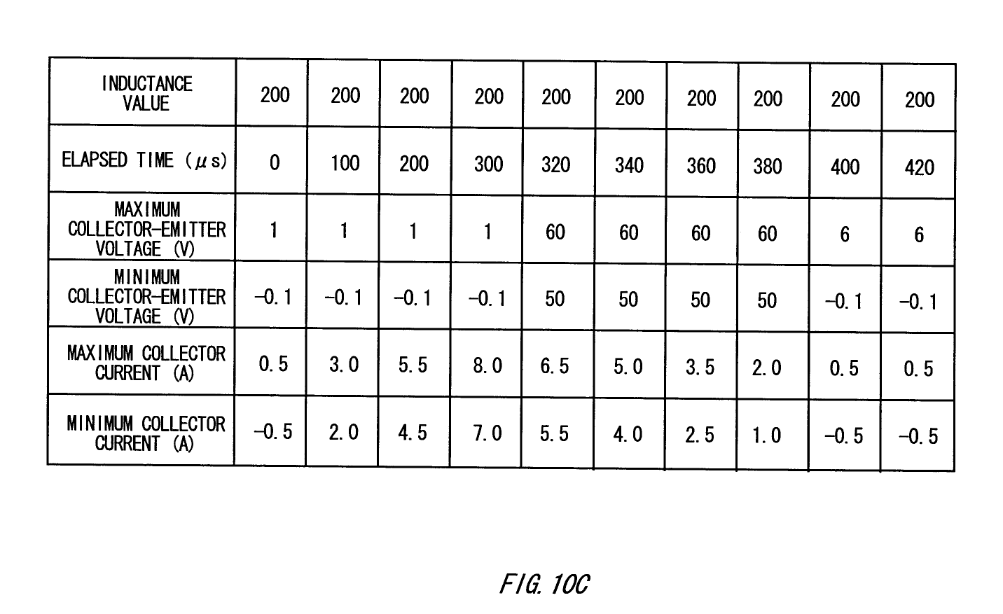

FIG. 10A shows exemplary data stored in the storage section 134. Here, “elapsed time” indicates the elapsed time that starts when the pulse signal begins to be supplied to the device under test 200, “maximum collector-emitter voltage” indicates the maximum value of the collector-emitter voltage allowable for the device under test 200 during the corresponding elapsed time, “minimum collector-emitter voltage” indicates the minimum value of the collector-emitter voltage allowable for the device under test 200 during the corresponding elapsed time, “maximum collector current” indicates the maximum value of the collector current allowed to flow through the device under test 200 during the corresponding elapsed time, and “minimum collector current” indicates the minimum value of the collector current allowed to flow through the device under test 200 during the corresponding elapsed time.

The storage section 134 may convert the values shown in FIG. 10A into binary and hold the converted values. The storage section 134 may hold, as the values indicating the maximum collector current and the minimum collector current, the voltage values output by the current detector 156 in correspondence with the maximum collector current and the minimum collector current.

In the example of FIG. 10A, the pulse width of the pulse signal supplied to the device under test 200 is 200 μs, and this assumes that the avalanche period in a correctly-operating device under test 200 is 100 μs. The storage section 134 may include the same data for each inductance value of the inductance load section 110.

The comparing section 136 compares the value of the collector current obtained via the AD converting section 137 to the values of the maximum collector current and the minimum collector current stored in association with the time measured by the measuring section 133. If a collector current of 8.0 A is acquired via the AD converting section 137 at an elapsed time of 250 μs, this indicates that the collector current flowing through the device under test 200 exceeds the maximum collector current, and therefore there is a high probability that the device under test 200 is malfunctioning. Therefore, the comparing section 136 switches the switching section 120 to the OFF state.

The comparing section 136 compares the value of the collector-emitter voltage obtained via the AD converting section 138 to the values of the maximum collector-emitter voltage and the minimum collector-emitter voltage stored in association with the time measured by the measuring section 133. If a collector-emitter voltage of 1.0 V is acquired via the AD converting section 138 at an elapsed time of 300 μs, this indicates that there is a high possibility that the device under test 200 is malfunctioning and operating in the short-circuit mode. Therefore, the comparing section 136 switches the switching section 120 to the OFF state.

FIG. 10B shows another example of data stored in the storage section 134. The data shown in FIG. 10B includes the inductance value of the inductance load section 110. Furthermore, the intervals of the elapsed time stored in association with the various types of data, such as the maximum collector current, are not uniform. More specifically, the intervals in the elapsed time from 200 μs onward, during which the supply of the pulse signal is stopped and the collector terminal 202 and the emitter terminal 204 of the device under test 200 are in the non-conductive state, are shorter than the intervals in the elapsed time from 0 to 200 μs, during which the pulse signal is supplied and the collector terminal 202 and the emitter terminal 204 of the device under test 200 are in the conductive state.

There is a high probability that the device under test 200 will malfunction in the avalanche period after the supply of the pulse signal is stopped. Therefore, by setting shorter intervals in the elapsed time after the supply of the pulse signal is stopped, damage to the device under test 200 can be detected more quickly while limiting the increase in the data amount stored in the storage section 134.

FIG. 10C shows other exemplary data stored in the storage section 134. The data shown in FIG. 10C differs from the data shown in FIG. 10B in that the inductance value is 200 μH instead of 100 μH. Furthermore, the elapsed time associated with each piece of data is different than in FIG. 10B.

When the inductance load section 110 has a large inductance value, the speed at which the collector current increases and decreases is lowered and the amount of electrical energy that can be accumulated in the inductance load section 110 is increased. Therefore, the test apparatus 100 can test the device under test 200 using different conditions by changing the inductance value of the inductance load section 110 and changing the time during which the pulse signal is supplied.

The storage section 134 may store at least one of the voltage between terminals of the device under test 200 and the collector current flowing through the device under test 200 in association with elapsed times corresponding to pulse signals with different pulse width according to the inductance value of the test apparatus 100. With this configuration, the test apparatus 100 can quickly detect damage to the device under test 200 regardless of the pulse signal width and the inductance value of the inductance load section 110, while also limiting the increase in the data amount to be stored in the storage section 134.

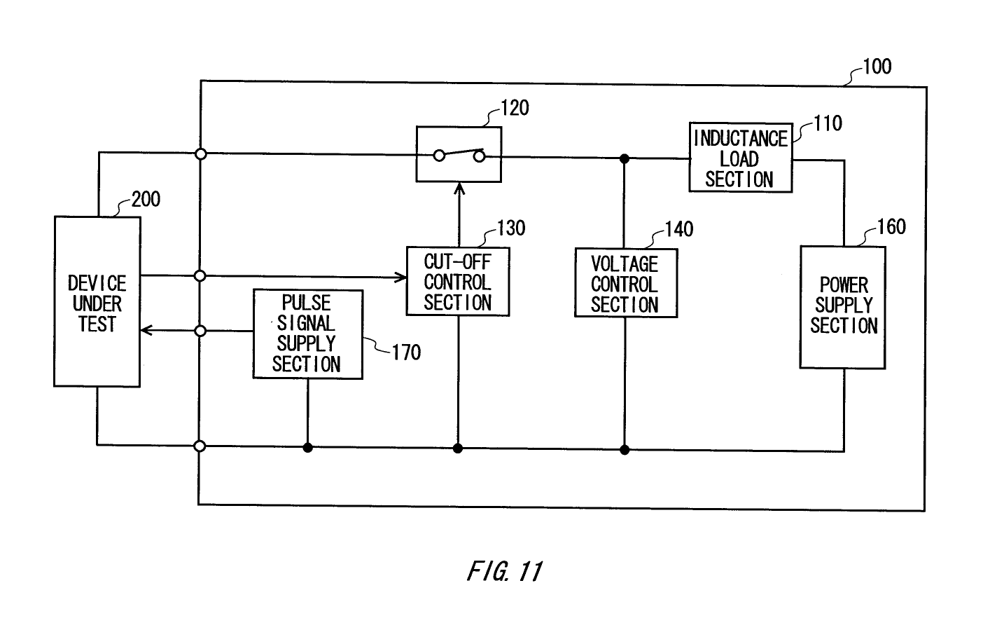

FIG. 11 shows an exemplary configuration of a test apparatus 100 according to another embodiment of the present invention. The test apparatus 100 of FIG. 11 differs from the test apparatus 100 shown in FIG. 1 by further including a power supply section 160 and a pulse signal supplying section 170. The power supply section 160 has the same function as the power supply section 300 shown in FIG. 1, and supplies power to the inductance load section 110. The pulse signal supplying section 170 has the same function as the pulse signal supplying section 400 in FIG. 1, and supplies the pulse signal to the device under test 200. The current supplied by the inductance load section 110 flows through the device under test 200 according to the pulse signal supplied from the pulse signal supplying section 170.

While the embodiments of the present invention have been described, the technical scope of the invention is not limited to the above described embodiments. It is apparent to persons skilled in the art that various alterations and improvements can be added to the above-described embodiments. It is also apparent from the scope of the claims that the embodiments added with such alterations or improvements can be included in the technical scope of the invention.

The operations, procedures, steps, and stages of each process performed by an apparatus, system, program, and method shown in the claims, embodiments, or diagrams can be performed in any order as long as the order is not indicated by “prior to,” “before,” or the like and as long as the output from a previous process is not used in a later process. Even if the process flow is described using phrases such as “first” or “next” in the claims, embodiments, or diagrams, it does not necessarily mean that the process must be performed in this order.

What is claimed is:

1. A test apparatus that tests a device under test, comprising:
an inductance load section that is provided in a path through which test current flows to the device under test and that has an inductance component;
a switching section that switches whether the test current is supplied to the device under test from the inductance load section;
a cut-off control section that severs the path by switching the switching section according to a state of the device under test; and
a voltage control section that controls voltage of the path between the inductance load section and the switching section to be no greater than a predetermined clamp voltage.

2. The test apparatus according to claim 1, wherein
the switching section is provided between the inductance load section and the device under test or between the device under test and a ground potential, and switches whether the current flowing through the path is cut off.

3. The test apparatus according to claim 1, wherein
the cut-off control section switches the switching section based on magnitude of the current flowing through the device under test or voltage between predetermined terminals of the device under test.

4. The test apparatus according to claim 3, wherein
the cut-off control section switches the switching section based on a result of a comparison between a predetermined reference value and the magnitude of the current flowing through the device under test or the voltage between the terminals of the device under test at a predetermined comparison timing.

5. The test apparatus according to claim 4, wherein the inductance load section includes:
a plurality of inductance loads; and
a selecting section that selects one or more of the inductance loads.

6. The test apparatus according to claim 5, wherein
the voltage control section controls the clamp voltage according to a combined inductance value of the one or more inductance loads selected by the inductance load section.

7. The test apparatus according to claim 5, wherein
the cut-off control section controls switching timing at which the switching section is switched, according to the combined inductance value of the one or more inductance loads selected by the inductance load section.

8. The test apparatus according to claim 5, wherein
the cut-off control section controls the comparison timing according to the combined inductance value of the one or more inductance loads selected by the inductance load section.

9. The test apparatus according to claim 5, wherein
the cut-off control section controls the reference value according to the combined inductance value of the one or more inductance loads selected by the inductance load section.

10. The test apparatus according to claim 4, further comprising a pulse signal supplying section that supplies the device under test with a pulse signal controlling the device under test to be in either a conductive state in which the test current flows therethrough or a non-conductive state in which the test current does not flow therethrough.

11. The test apparatus according to claim 10, wherein
when a predetermined time has passed since the pulse signal was supplied to the device under test, the cut-off control section switches the switching section to an OFF state regardless of the state of the device under test.

12. The test apparatus according to claim 10, wherein
the voltage control section controls the clamp voltage according to length of time during which the pulse signal is supplied to the device under test.

13. The test apparatus according to any one of claims 10 to 12, wherein the voltage control section includes:
a reference voltage generating section that generates a reference voltage corresponding to the clamp voltage; and
a diode having a cathode connected to the reference voltage generating section and an anode connected between the inductance load section and the switching section.

14. The test apparatus according to claim 10, wherein the voltage control section includes:
a reference voltage generating section that generates a reference voltage corresponding to the clamp voltage; and
a switch that switches whether the reference voltage generating section is connected to the inductance load section and the switching section, according to the state of the switching section.

15. The test apparatus according to claim 10, wherein
the cut-off control section includes:
a measuring section that measures one of a first elapsed time from when the supply of the pulse signal to the device under test begins and a second elapsed time from when the supply of the pulse signal to the device under test is stopped;
a storage section that stores, in association with the measured elapsed time, at least one of a minimum value and a maximum value allowed for magnitude of the current flowing through the device under test; and
a comparing section that compares the at least one of the minimum value and the maximum value stored in the storage section to the magnitude of the current flowing through the device under test, and
when the magnitude of the current flowing through the device under test at a predetermined comparison timing is less than the minimum value associated with the measured elapsed time corresponding to the comparison timing, or when the magnitude of the current flowing through the device under test at the predetermined comparison timing is greater than the maximum value associated with the measured elapsed time corresponding to the comparison timing, the comparing section switches the switching section to cut off the supply of the test current from the inductance load section to the device under test.

16. The test apparatus according to claim 10, wherein
the cut-off control section includes:
a measuring section that measures one of a first elapsed time from when the supply of the pulse signal to the device under test begins and a second elapsed time from when the supply of the pulse signal to the device under test is stopped;
a storage section that stores, in association with the measured elapsed time, at least one of a minimum value and a maximum value allowed for voltage between predetermined terminals of the device under test; and
a comparing section that compares the at least one of the minimum value and the maximum value stored in the storage section to the voltage between the predetermined terminals of the device under test, and
when the voltage between the predetermined terminals of the device under test at a predetermined comparison timing is less than the minimum value associated with the measured elapsed time corresponding to the comparison timing, or when the voltage between the predetermined terminals of the device under test at the predetermined comparison timing is greater than the maximum value associated with the measured elapsed time corresponding to the comparison timing, the comparing section switches the switching section to cut off the supply of the test current from the inductance load section to the device under test.

17. The test apparatus according to claim 15, wherein
the storage section stores at least one of the minimum value and the maximum value corresponding to the elapsed time, in association with an inductance value of the inductance load section, and
the cut-off control section switches the switching section based on the at least one of the minimum value and the maximum value corresponding to the inductance value of the inductance load section read from the storage section, according to the inductance value of the inductance load section.

18. The test apparatus according to claim 1, wherein
the device under test is a semiconductor device including a first terminal for receiving the test current, a second terminal for outputting the test current, and a third terminal for controlling the magnitude of the test current flowing between the first terminal and the second terminal, according to voltage or current input thereto, and
the cut-off control section switches the switching section according to the voltage between the first terminal and the second terminal or the voltage between the second terminal and the third terminal.

19. The test apparatus according to claim 1, further comprising a power supply section that supplies current input to the inductance load section.

20. A test method for testing a device under test, comprising:
controlling a switching section that switches whether test current is supplied to the device under test from an inductance load section having an inductance component and provided in a path through which the test current flows to the device under test, to sever the path according to a state of the device under test; and
controlling voltage of the path between the inductance load section and the switching section to be no greater than a predetermined clamp voltage.
